(19) United States
(12) Patent Application Publication
(10) Pub. No.: US 2023/0386830 A1
(43) Pub. Date: Nov. 30, 2023

(54) HIGHLY CONFORMAL METAL ETCH IN HIGH ASPECT RATIO SEMICONDUCTOR FEATURES

(71) Applicant: Applied Materials, Inc., Santa Clara, CA (US)

(72) Inventors: Xiaolin C. Chen, San Ramon, CA (US); Baiwei Wang, Santa Clara, CA (US); Rohan Puligoru Reddy, San Jose, CA (US); Wanxing Xu, Sunnyvale, CA (US); Zhenjiang Cui, San Jose, CA (US); Anchuan Wang, San Jose, CA (US)

(73) Assignee: Applied Materials, Inc., Santa Clara, CA (US)

(21) Appl. No.: 17/827,356

(22) Filed: May 27, 2022

(51) Int. Cl. H01L 21/02; H01L 29/423; H01L 29/49; H01L 21/311

(52) U.S. Cl. CPC H01L 21/02244; H01L 29/42392; H01L 29/495; H01L 21/31122

(57) ABSTRACT

Exemplary semiconductor processing methods may include providing an oxygen-containing precursor to a semiconductor processing chamber, where a substrate may be positioned. The substrate may include a trench formed between two columns and molybdenum-containing metal regions in a plurality of recesses formed in at least one of the columns. At least two of the molybdenum-containing metal regions may be connected by a molybdenum-containing first liner formed on at least a portion of a sidewall of the trench. The methods may include forming a plasma of the oxygen-containing precursor. The methods may include contacting the molybdenum-containing first liner with plasma effluents of the oxygen-containing precursor, thereby forming an oxidized portion of molybdenum. The methods may include providing a halide precursor. The methods may include contacting oxidized portion of the molybdenum with plasma effluents of the halide precursor, thereby removing the oxidized portion of molybdenum from the sidewall of the trench.

### TECHNICAL FIELD

The present technology relates to semiconductor processes and equipment. More specifically, the present technology relates to laterally etching molybdenum in vertical structures.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing an oxygen-containing precursor to a semiconductor processing chamber. A substrate may be positioned within the semiconductor processing chamber. The substrate may include a trench formed between columns and molybdenum-containing metal regions in a plurality of recesses formed in at least one of the columns. At least two of the molybdenum-containing metal regions may be connected by a molybdenum-containing first liner formed on at least a portion of a sidewall of the trench. The methods may include forming a plasma of the oxygen-containing precursor in the semiconductor processing chamber. The methods may include contacting the molybdenum-containing first liner with plasma effluents of the oxygen-containing precursor. The contacting may form an oxidized portion of molybdenum on the molybdenum-containing first liner. The methods may include providing a halide precursor to the semiconductor processing chamber. The methods may include contacting the oxidized portion of the molybdenum with plasma effluents of the halide precursor. The contacting may remove the oxidized portion of molybdenum from the sidewall of the trench.

In some embodiments, the oxygen-containing precursor may be or include ozone. The plasma of the oxygen-containing precursor may be formed at a plasma power less than or about 2,000 W. The oxidized portion of molybdenum may be characterized by a thickness of less than or about 100 Å. The halide precursor may be or include a fluorine-containing precursor. The fluorine-containing precursor may be or include tungsten hexafluoride. Forming the oxidized portion of molybdenum may produce a layer of molybdenum oxide formed along a sidewall of the trench. A thickness of the layer of molybdenum oxide proximate an upper region of the trench may differ in thickness from the layer of molybdenum oxide proximate a lower region of the trench by less than or about 30%. The substrate may further include a second liner disposed adjacent to the molybdenum-containing metal regions and the molybdenum-containing first liner. The methods may further include providing a fluorine-containing precursor to the semiconductor processing chamber, forming a plasma of the fluorine-containing precursor to produce fluorine-containing plasma effluents, contacting the second liner with the fluorine-containing plasma effluents to form a fluorinated portion of the second liner, providing a chlorine-containing precursor to the semiconductor processing chamber, forming a plasma of the chlorine-containing precursor to produce chlorine-containing plasma effluents, and contacting the fluorinated portion of the second liner with the chlorine-containing plasma effluents. The contacting may remove the fluorinated portion of the second liner. The contacting of the molybdenum-containing first liner with plasma effluents of the oxygen-containing precursor and the contacting the oxidized portion of molybdenum with plasma effluents of the halide precursor may be repeated at least two times.

Some embodiments of the present technology encompass semiconductor processing methods. The methods may include i) forming plasma effluents of an oxygen-containing precursor. The methods may include ii) contacting a molybdenum-containing first liner connecting at least two molybdenum-containing metal regions arranged within a plurality of recesses defined by at least one column of a trench with plasma effluents of the oxygen-containing precursor. The contacting may form an oxidized portion of molybdenum on the molybdenum-containing first liner. The methods may include iii) forming plasma effluents of a fluorine-containing precursor. The methods may include iv) contacting the oxidized portion of molybdenum with plasma effluents of the fluorine-containing precursor. The contacting may remove the oxidized portion of molybdenum.

In some embodiments, operations i) through iv) may be repeated at least two times. The oxygen-containing precursor may be or include ozone. The fluorine-containing precursor may be or include tungsten hexafluoride. A temperature may be maintained at between about 200° C. and about 600° C. during operations i) and ii). A pressure may be maintained at less than or about 20 Torr during operations i) and ii). The methods may include adjusting a temperature, a pressure, or both prior to contacting the oxidized portion of molybdenum with plasma effluents of the fluorine-containing precursor. A second liner may be disposed adjacent to the molybdenum-containing metal regions and the molybdenum-containing first liner. The methods may further include forming a plasma of a fluorine-containing precursor to produce fluorine-containing plasma effluents. The fluorine-containing precursor may be or include nitrogen trifluoride. The methods may further include contacting the second liner with the fluorine-containing plasma effluents to form a fluorinated portion of the second liner and forming a plasma of a chlorine-containing precursor to produce chlorine-containing plasma effluents. The chlorine-containing precursor may be or include boron trichloride. The methods may further include contacting the fluorinated portion of the second liner with the chlorine-containing plasma effluents. The contacting may remove the fluorinated portion of the second liner. The second liner may be or include an oxygen-containing material, a nitrogen-containing material, or an oxygen-and-nitrogen-containing material.

Some embodiments of the present technology encompass semiconductor structures. The structures may include a substrate. The structures may include a silicon-containing material overlying the substrate. The substrate may include a trench formed between columns. At least one column may define a plurality of recesses. The structures may include a liner extending along the at least one column and into the plurality of recesses. The structures may include molybdenum-containing metal regions formed in the plurality of recesses. The molybdenum-containing metal regions may be partially surrounded by the liner. A thickness of the molybdenum-containing metal regions in a recess proximate an upper region of the trench may differ in thickness from the molybdenum-containing metal regions in a recess proximate a lower region of the trench by less than or about 30%.

In some embodiments, the trench may be characterized by a depth of greater than or about 5 μm. The molybdenum-containing metal regions may be surrounded by the liner on three sides. The molybdenum-containing metal regions in one recess may be isolated from molybdenum material in a remaining plurality of recesses.

Such technology may provide numerous benefits over conventional systems and techniques. For example, the processes may provide uniform top to bottom etching of molybdenum-containing metal inside a trench. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to embodiments of the present technology.

FIG. 2A shows a schematic cross-sectional view of an exemplary processing chamber according to embodiments of the present technology.

FIG. 2B shows a detailed view of a portion of the processing chamber illustrated in FIG. 2A according to embodiments of the present technology.

FIG. 3 shows a bottom plan view of an exemplary showerhead according to embodiments of the present technology.

FIG. 4 shows exemplary operations in a method according to embodiments of the present technology.

FIGS. 5A-5D show cross-sectional views of substrates being processed according to embodiments of the present technology.

FIG. 6 shows exemplary operations in a method according to embodiments of the present technology.

FIGS. 7A-7D show cross-sectional views of substrates being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The growing demands of mobile computing and data centers continue to drive the need for high-capacity, high-performance NAND flash technology. With planar NAND nearing its practical scaling limits, 3D NAND is replacing 2D NAND for memory devices. Manufacturing 3D NAND structures may require depositing alternating layers of two or more materials. For example, in some structures, alternating layers of silicon oxide and silicon may be used, or alternating layers of silicon oxide and silicon nitride, or alternating layers of silicon oxide and molybdenum, among other combinations, with a total thickness of the stacked layers up to several microns. These stacked layers may be etched into trenches or contact holes. Additionally, one of these two alternating materials, or at least a portion thereof, may be etched selectively from the trenches to form memory cells. For example, silicon, silicon nitride, or molybdenum are the respective materials that need to be removed at least partially in the silicon oxide and silicon, silicon oxide and silicon nitride, or silicon oxide and molybdenum alternating layers. If a liner material is utilized when forming the stacked layers, such as an aluminum oxide, hafnium oxide, titanium nitride, tantalum nitride, or hafnium nitride liner formed between silicon oxide and molybdenum, the liner may also need to be removed.

In transitioning from 2D NAND to 3D NAND, many process operations, such as the etching operation for forming the memory cells, are modified from vertical to horizontal operations. Additionally, as 3D NAND structures grow in the number of cells being formed, the aspect ratios of the trenches, contact holes, and other structures increase, sometimes dramatically. Because of the high aspect ratio (>10:1) of the trenches, one common challenge involves uniformly etching the materials, such as molybdenum and liner materials discussed above, from top to bottom within the feature. Wet methods are conventionally used for these applications, however the wet etching may etch the materials further than necessary or desired. For example, the wet etching may etch each layer significantly, and may etch each layer almost through completely to other memory holes, which may make placing the cell layers in the appropriate or desired locations more difficult, and may weaken the structures causing deformation. Additionally, as structures continue to shrink in size, the surface tension of fluids used in wet etching can cause pattern collapse or sticking issues.

Traditional plasma dry etching has also been explored for these applications. Because plasma etching can be anisotropic and directional, it may be used to clear the materials on the top and the bottom of the trenches, but it may have difficulty in recessing the sidewalls of the memory holes uniformly. Plasma dry etching may be combined with wet etching: with one to etch the top and the bottom, and the other to etch the sidewalls. In this case, however, two steps are needed, which increases the processing time and costs.

The present technology overcomes these issues by performing a dry etch process that allows uniform top to bottom etching of molybdenum-containing metal and/or liner material inside trenches of high aspect ratios. By oxidizing the molybdenum-containing metal, an oxide layer with a substantially uniform thickness from the top to the bottom of the trenches may be formed. By subsequently supplying a halide precursor to selectively etch only the oxidized layer by the preceding oxidation operation, a uniform etching of the molybdenum-containing metal from the top to the bottom inside the trenches may be achieved. Similarly, by treating the liner material with a fluorine, a fluorinated layer with a substantially uniform thickness from the top to the bottom of the trenches may be formed. By subsequently supplying a chlorine precursor to selectively etch only the oxidized layer by the preceding oxidation operation, a uniform etching of the liner material from the top to the bottom inside the trenches may be achieved.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the operations described.

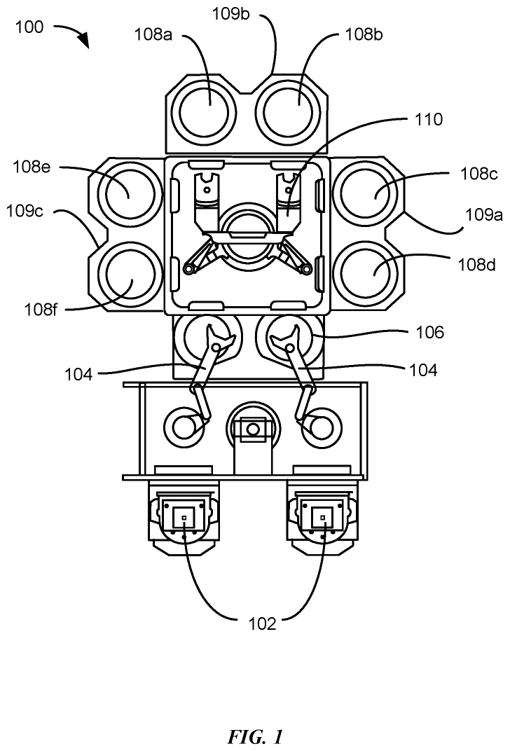

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric or metallic film on the substrate wafer. In one configuration, two pairs of the processing chambers, e.g., 108c-d and 108e-f, may be used to deposit material on the substrate, and the third pair of processing chambers, e.g., 108a-b, may be used to etch the deposited material. In another configuration, all three pairs of chambers, e.g., 108a-f, may be configured to etch a dielectric or metallic film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

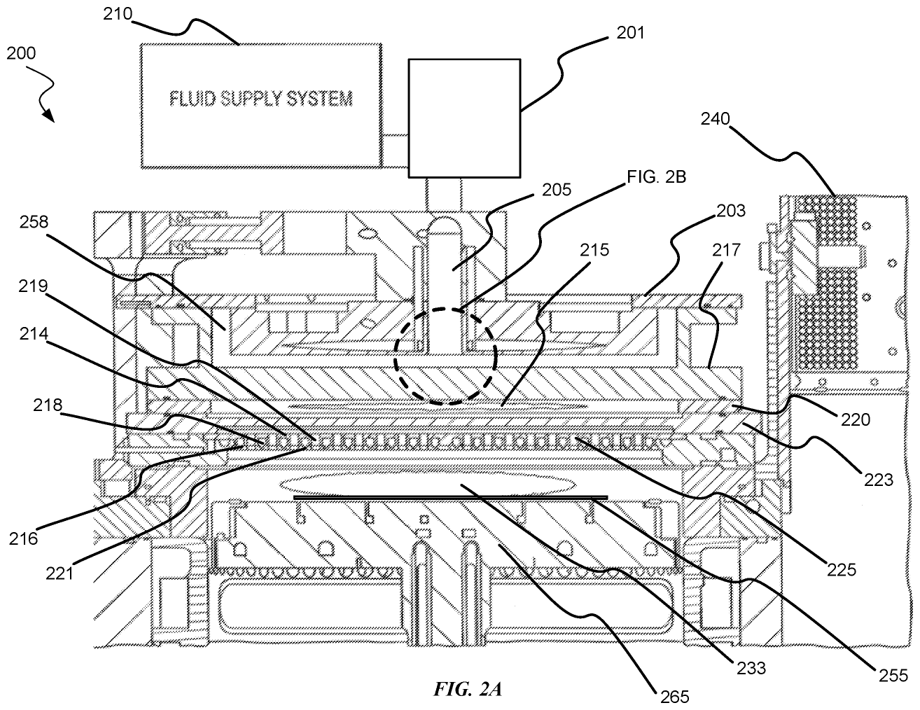

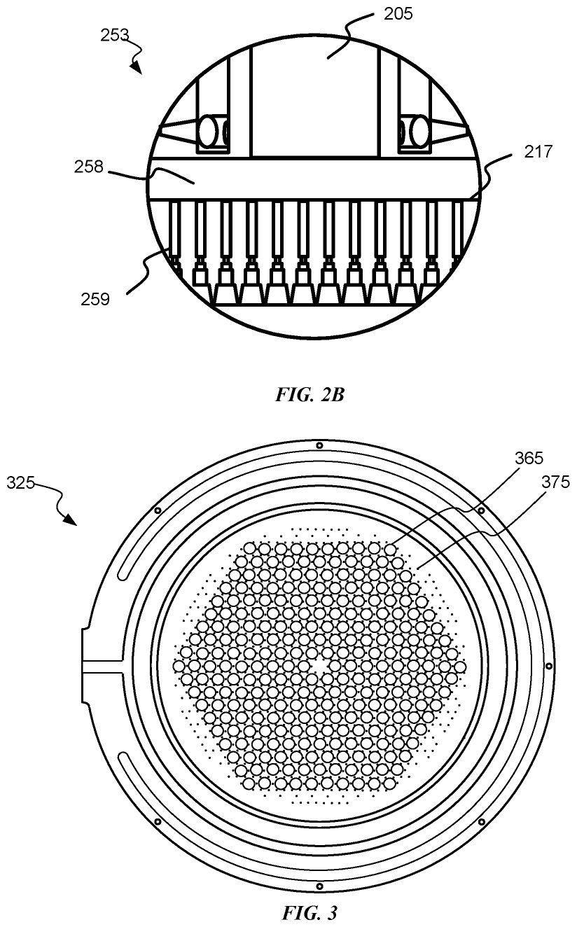

FIG. 2A shows a cross-sectional view of an exemplary process chamber system 200 with partitioned plasma generation regions within the processing chamber. During film etching, e.g., titanium nitride, tantalum nitride, molybdenum, tungsten, copper, cobalt, silicon, polysilicon, silicon oxide, silicon nitride, silicon oxynitride, silicon oxycarbide, etc., a process gas may be provided to the first plasma region 215 through a gas inlet assembly 205. A remote plasma system (RPS) 201 may optionally be included in the system, and may process a first gas which then travels through gas inlet assembly 205. The gas inlet assembly 205 may include two or more distinct gas supply channels where the second channel (not shown) may bypass the RPS 201, if included.

A cooling plate 203, faceplate 217, ion suppressor 223, showerhead 225, and a pedestal 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 600° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the gas supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or substrate processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet assembly 205. The gases may fill the gas supply region and flow to first plasma region 215 through apertures 259 in faceplate 217. The apertures may be configured to direct flow in a substantially unidirectional manner such that process gases may flow into substrate processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the substrate processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the showerhead 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

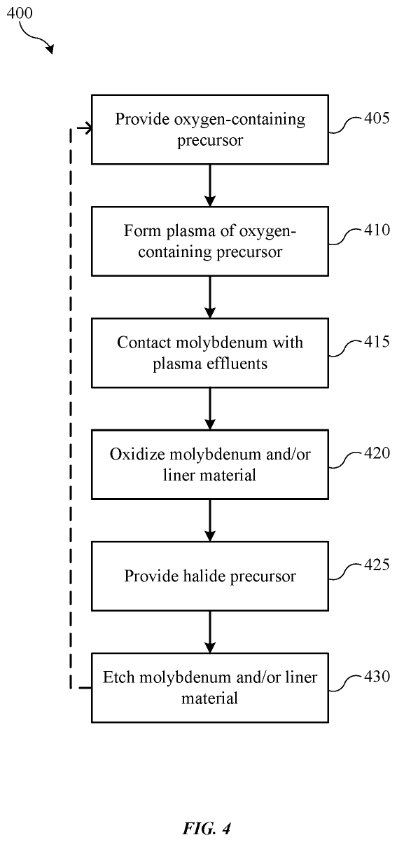

The chambers discussed previously may be used for performing exemplary methods including etching methods. Turning to FIG. 4, exemplary operations in method 400 are shown according to embodiments of the present technology. Prior to the first operation of method 400, a substrate may be processed in one or more ways. For example, inter-poly dielectric (IPD) layers may be formed on the substrate. The IPD layers may include any number of materials, and may include alternating layers of a placeholder material and a dielectric material. In embodiments the dielectric material may be or include silicon oxide, and the placeholder material may be or include silicon nitride. One or more trenches or memory holes may be formed through the stacked IPD layers, and the trenches may divide the IPD layers into vertical columns to be further processed into 3D NAND structures. For example, layers of the placeholder material or at least portions thereof may be removed to form lateral recesses along sidewalls of the vertical columns. Then the lateral recesses may be lined with a gate dielectric and filled by a gate metal to form the gate structure of 3D NAND. In embodiments the gate dielectric may be or include aluminum oxide, and the gate metal may be or include molybdenum, tungsten, cobalt, or any other conductive material.

A gate metal barrier may also be formed between the gate metal and the gate dielectric and/or between the gate metal and the dielectric material of the IPD layers. The gate metal barrier may be or include a metal, a metal oxide, or a metal nitride, such as hafnium, titanium, tantalum, aluminum oxide, hafnium oxide, hafnium nitride, titanium nitride, tantalum nitride. Typically, the gate metal may be deposited from top to bottom into the trenches and inside the lateral recesses formed along the sidewalls of the trenches to form metal regions interposed between the layers of the dielectric material of the IPD layers. During deposition, the gate metal may also be deposited outside the lateral recesses, lining portions of the sidewalls of the trenches and connecting the metal regions. Such lining or connecting metal may be removed so as to separate the metal regions from each other to prevent crosstalk or shorting between the cells. Some or all of the operations may be performed in chambers or system tools as previously described, or may be performed in different chambers on the same system tool, which may include the one or more chambers in which the operations of method 400 are performed to remove the connecting metal lining the sidewalls of the trench.

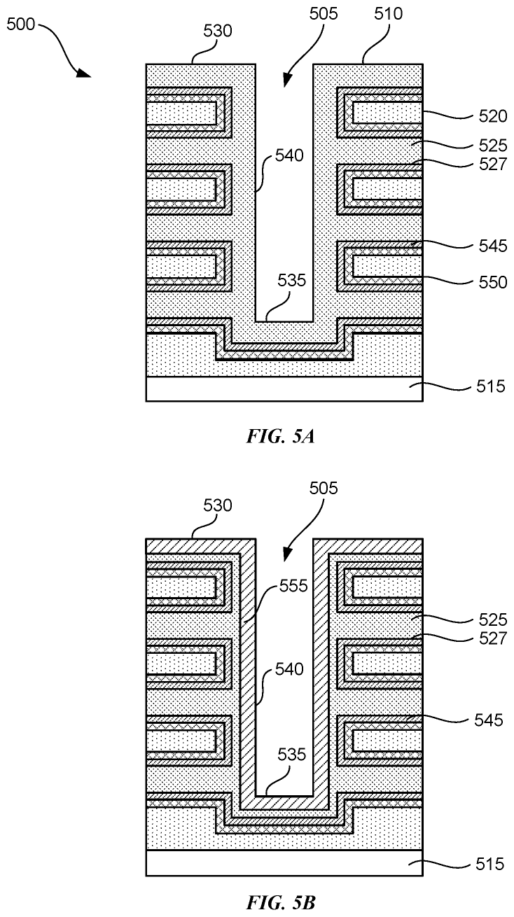

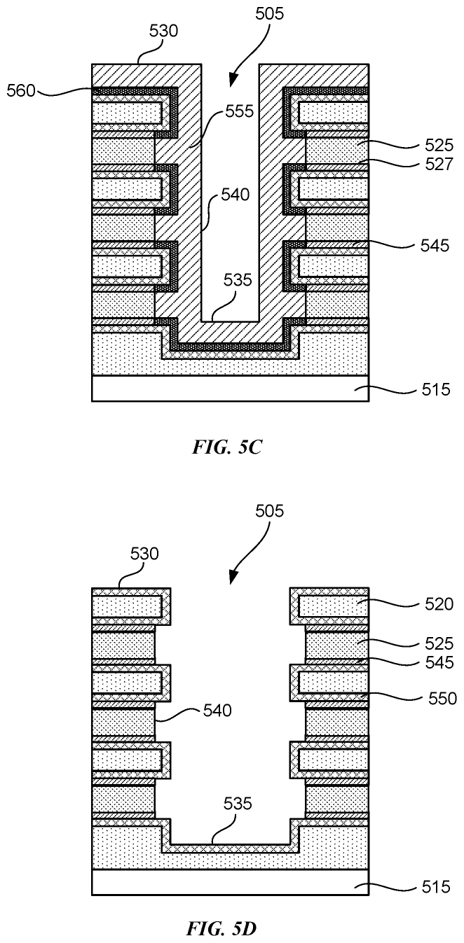

The operations of method 400 will now be described in conjunction with the schematic illustration of FIGS. 5A-5D. FIG. 5A illustrates a portion of a processed structure 500 to be further developed in producing 3D NAND structures. The processed structure 500 may include one or more trenches 505 (only one shown) formed between adjacent vertical columns 510 of stacked layers overlying a substrate 515. The stacked layers may include dielectric layers and metal layers or metal regions interposed between the dielectric layers for forming the gate structure of each memory cell. The dielectric layers may include oxide layers, such as silicon oxide layers 520 as shown in FIG. 5A. The metal regions may include molybdenum regions, such as molybdenum regions 525 as shown in FIG. 5A. The molybdenum regions 525 may be formed by depositing molybdenum in lateral recesses 527 created by removing layers, or portions thereof, of a placeholder material. When forming the molybdenum regions 525, molybdenum may also be deposited along the top 530, bottom 535, and sidewalls 540 of the trench 505 and may connect two or more of the molybdenum regions 525. The processed structure 500 may further include one or more barrier materials or liner materials, such as gate metal barriers and gate dielectric, which may collectively or individually be referred to as a second liner. The gate metal barriers may include oxide, nitride, or oxygen-and-nitrogen barriers, such as oxide or nitride barriers 545 (e.g., aluminum oxide, hafnium oxide, titanium nitride, tantalum nitride, hafnium nitride, etc.) as shown in FIG. 5A. The oxide or nitride barriers, again referred to as a second liner, may be disposed adjacent to the molybdenum-containing metal regions and/or the molybdenum-containing first liner. The gate dielectric may include aluminum oxide gate dielectric, such as gate dielectric 550 (e.g., aluminum oxide) as shown in FIG. 5A. The oxide or nitride barriers 545 may be a metal-containing oxide or nitride material. It is contemplated that the processed structure 500 may include only one of the oxide or nitride barriers 545 and the gate dielectric 550.

Although FIG. 5A illustrates only 4 layers of dielectric material and 4 layers of metal, the processed structure 500 may include any number of layers of each material, such as up to or greater than about 10, greater than or about 15, greater than or about 20, greater than or about 25, greater than or about 30, greater than or about 35, greater than or about 40, greater than or about 45, greater than or about 50, greater than or about 55, greater than or about 60, greater than or about 65, greater than or about 70, greater than or about 80, greater than or about 90, greater than or about 100, or more layers of materials. This may produce trenches with a width of a few hundreds of nanometers, or tens of nanometers, or less, while the height thereof may be on the order of a few microns, or tens of microns, or more. The resulting aspect ratios or height to width ratios of the trenches may be greater than 20:1, greater than 50:1, greater than 75:1, greater than 100:1, or even greater. In embodiments, the trenches may be characterized by a width of less than or about 200 nm, or less, and/or a depth of greater than or about 5 micron. As discussed above, molybdenum-containing material formed on the bottom and/or the sidewalls of the trenches may be removed in order to separate the molybdenum regions from each other. Because of the high aspect ratios of the trenches, traditional dry etching methods have difficulty in achieving uniform etching of the molybdenum metal from the top to the bottom of the trenches, also called a 1:1 ratio of top-to-bottom loading. As will be described in more detail below, method 400 in accordance with some embodiments of the present technology improves the top to bottom loading and may produce substantially uniform etching of the molybdenum metal inside the trenches.

As illustrated in FIG. 5B, method 400 may include initially oxidizing the molybdenum-containing first liner formed on the top 530, bottom 535, and/or sidewalls 540 of the trench 505 to form a molybdenum oxide 555 inside and on top of the trench 505. In some embodiments, to oxidize molybdenum, the substrate 515 may be positioned within a processing region of a semiconductor processing chamber, such as the substrate processing region 233 of the processing chamber system 200 discussed above with reference to FIG. 2A. Once positioned within the processing region, method 400 may be initiated by providing an oxygen-containing precursor to a remote plasma region of the semiconductor processing chamber at operation 405. The remote plasma region may be fluidly coupled with the processing region, although it may be physically partitioned to limit plasma at the substrate level, which may damage exposed structures or materials on the substrate 515. In some embodiments, the remote plasma region may include a remote plasma system (RPS) fluidly coupled with an inlet to the semiconductor processing chamber, such as the RPS 201 discussed above. In some embodiments, the remote plasma region may include a capacitively-coupled plasma (CCP) region, such as the first plasma region formed by capacitively coupling the faceplate 217 and the showerhead 225 and/or ion suppressor 223, and the CCP region may be physically separated from the processing region by one of its electrodes, such as the showerhead 225 and/or ion suppressor 223. Method 400 may further include forming a plasma of the oxygen-containing precursor at operation 410 to produce oxygen-containing plasma effluents, and providing the oxygen-containing plasma effluents to the processing region at operation 415. At operation 420, the molybdenum connecting the molybdenum regions 525 may be oxidized to form the molybdenum oxide 555 inside and on top of the trench 505 as shown in FIG. 5B.

The oxygen-containing precursor may include a variety of fluids, and may include one or more of atomic oxygen, molecular oxygen (O₂), N₂O, NO, NO₂, CO₂, ozone (O₃), or any other oxygen-containing precursor that may similarly perform the oxidation operation. The oxygen-containing precursor may be provided at a rate of at least 1000 sccm, and may be provided at a rate greater than or about 2000 sccm, greater than or about 3000 sccm, greater than or about sccm, greater than or about 5000 sccm, greater than or about 6000 sccm, greater than or about 7000 sccm, greater than or about 8000 sccm, greater than or about 9000 sccm, or more in embodiments. In some embodiments, the flow of the oxygen-containing precursors may be pulsed. The flow of the oxygen-containing precursors may be pulsed for time periods of less than or about 60 seconds in embodiments, and may be pulsed for time periods of less than or about 55 seconds, less than or about 50 seconds, less than or about 45 seconds, less than or about seconds, less than or about 35 seconds, less than or about 30 seconds, less than or about 25 seconds, less than or about 20 seconds, less than or about 15 seconds, less than or about 10 seconds, less than or about 5 seconds, or less.

During the flow of the oxygen-containing precursors, the flow rate of the oxygen-containing precursor may be maintained at relatively high levels such that sufficient or even more than sufficient oxygen may be present from the top to the bottom of the trenches to fully oxidize the molybdenum connecting the molybdenum regions. In some embodiments, ample supply of oxygen may further improve the uniformity of the thickness of the molybdenum oxide layer formed inside the trenches. The uniformity may occur in part due to the initial rapid oxidization occurring at the neat or clean molybdenum surface. Specifically, method 400 may be performed after molybdenum has been deposited inside the trenches but before any atmospheric exposure. The oxidation rate at the neat molybdenum surface may be sufficiently rapid that with ample supply of oxygen, the molybdenum proximate the bottom of the trenches may be almost simultaneously oxidized to a thickness that may be substantially the same as that of the molybdenum oxidized proximate the top of the trenches. As oxidation penetrates the surface of the metal, the oxidation rate may decrease dramatically, and may in some embodiments reach a saturation depth at which minimal or no further oxidation may continue to occur at chamber conditions. Accordingly, metal located at a location further from initial contact of the plasma effluents, such as at the bottom of the trench, may be oxidized to a similar or substantially similar depth as at the top of the trench despite the longer residence time at locations proximate the top of the trench.

In some embodiments, the initial rapid oxidization may produce a molybdenum oxide layer having a thickness of greater than or about 10 Å, greater than or about 15 Å, greater than or about 20 Å, greater than or about 25 Å, greater than or about 30 Å, greater than or about 35 Å, greater than or about 40 Å, greater than or about 50 Å, greater than or about 60 Å, greater than or about 70 Å, greater than or about 80 Å, greater than or about 90 Å, greater than or about 100 Å, or more, before the oxidization process slows down. In some embodiments, by adjusting the processing conditions, the initial rapid oxidization may produce a molybdenum oxide layer having a thickness of less than or about 100 Å, less than or about 900 Å, less than or about 80 Å, less than or about 70 Å, less than or about 60 Å, less than or about 50 Å, less than or about 40 Å, or less. The thickness of the molybdenum oxide layer proximate an upper region of the trenches may differ from the thickness of the molybdenum oxide layer proximate a lower region of the trenches by less than or about 30%, less than or about 25%, less than or about 20%, less than or about 15%, less than or about 10%, less than or about 5%, less than or about 3%, less than or about 1%, or less in embodiments. Accordingly, a ratio of less than or about 1.3:1, less than or about 1.25:1, less than or about 1.2:1, less than or about 1.15:1, less than or about 1.1:1, less than or about 1.05:1, or a ratio of substantially or essentially 1:1 top to bottom loading of molybdenum oxidation as shown in FIG. 5B may be achieved utilizing method 400. Given the initial rapid oxidation, the flow of the oxygen-containing precursor may be maintained for time periods of less than or about 15 minutes, less than or about 10 minutes, less than or about 5 minutes, less than or about 3 minutes, less than or about 2 minutes, less than or about 90 seconds, less than or about 60 seconds, less than or about 50 seconds, less than or about 40 seconds, less than or about 30 seconds, less than or about 25 seconds, less than or about 20 seconds, less than or about 15 seconds, less than or about 10 seconds, less than or about 5 seconds, or less. In some embodiments, to facilitate sufficient oxidation, the flow of the oxygen-containing precursor may be maintained for time periods greater than or about 5 seconds, greater than or about 10 seconds, greater than or about 30 seconds, greater than or about 1 minute, greater than or about 5 minutes, greater than or about 10 minutes, greater than or about 15 minutes, or more. Accordingly, in some embodiments, the flow of the oxygen-containing precursor may be maintained between about 5 seconds and about 15 minutes, between about 30 seconds and about 10 minutes, between about 1 minute to about 5 minutes, or any other suitable time period.

The oxygen-containing precursor may also include any number of carrier gases, which may include nitrogen, helium, argon, or other noble, inert, or useful precursors. The carrier gases may be used to enhance uniform distribution of the oxygen-containing precursor inside the trenches, which may further improve top to bottom loading for the oxidation operation 420. In some embodiments, a flow rate of the carrier gas may be maintained less than or about 50% of the oxygen-containing precursor flow rate, or may be less than or about 40%, less than or about 30%, less than or about 20%, less than or about 10%, less than or about 5%, less than or about 3%, or less than or about 1% of the oxygen-containing precursor flow rate, or less. By adjusting the composition and/or the respective flow rates of the components of the oxygen-containing precursor, uniform delivery of the oxygen-containing plasma effluents inside the trench may be achieved, thereby further improving the uniformity of molybdenum oxidation from the top to the bottom of the trenches.

Other process conditions may also impact the uniformity of molybdenum oxidation from the top to the bottom of the trenches, such as plasma power, operating temperature, operating pressure, etc. In embodiments where the oxygen-containing plasma may be formed in a remote plasma system, the plasma power may be less than or about 2,000 W, and may be less than or about 1,500 W, less than or about 1,000 W, less than or about 750 W, less than or about 500 W, less than or about 250 W, or less, to facilitate the dissociation of the oxygen-containing precursors. In embodiments where the oxygen-containing plasma may be formed in a capacitively-coupled plasma (CCP) region of the semiconductor processing chamber, lower plasma powers may be utilized so as to prevent damage to structures on the substrate. The plasma power in the CCP region may be at least 50 W, and may be greater than or about 100 W, greater than or about 150 W, greater than or about 200 W, greater than or about 250 W, greater than or about 300 W, greater than or about 350 W, greater than or about 400 W, greater than or about 450 W, greater than or about 500 W, or more in embodiments. The plasma power in the CCP region may be less than or about 2,500 W, and may be less than or about 2,000 W, less than or about 1,500 W, less than or about 1,000 W, less than or about 750 W, less than or about 500 W, less than or about 250 W, or less.

To facilitate rapid oxidation and thereby improve top to bottom loading, the temperature within the processing chamber or at the substrate level may be maintained between about 200° C. and about 600° C. in embodiments. The temperature may be maintained above or about 200° C., and may be maintained above or about 250° C., above or about 300° C., above or about 350° C., above or about 400° C., above or about 450° C., above or about 500° C., above or about 550° C., above or about 600° C., or higher. The higher the temperature that may be maintained during the oxidation operation 420, the faster the molybdenum may be oxidized, and the more uniform the thickness of the molybdenum oxide layer may be. During the oxidation operation 420, a pressure within the processing chamber may be maintained below or about 20 Torr in embodiments. The pressure may be maintained below or about 15 Torr, and may be maintained below or about 10 Torr, below or about 5 Torr, below or about 4 Torr, below or about 3 Torr, below or about 2 Torr, below or about 1 Torr, below or about 100 mTorr, or lower. In embodiments the pressure may be maintained between about 500 mTorr and about 10 Torr. Maintaining a relatively low pressure inside the processing chamber may facilitate the distribution of the oxygen-containing plasma effluents into the trench, resulting in uniform top to bottom oxidation as discussed above.

Although FIG. 4 illustrates oxidizing molybdenum and/or liner material using oxygen-containing plasma, a non-plasma process may be utilized. Accordingly, in some embodiments, operations 410 and 415 of method 400 may be omitted. The oxygen-containing precursor, such as one or more of atomic oxygen, molecular oxygen (02), ozone (03), or other oxygen-containing precursors, may be provided to the processing region to oxidize molybdenum and/or liner material. In the embodiments where molecular oxygen may be utilized for oxidizing molybdenum and/or liner material, the temperature within the processing chamber or at the substrate level may be maintained between about 250° C. and about 600° C. The temperature may be maintained above or about 250° C., and may be maintained above or about 300° C., above or about 350° C., above or about 400° C., above or about 450° C., above or about 500° C., above or about 550° C., above or about 600° C., or higher. In the embodiments where ozone may be utilized for oxidizing molybdenum and/or liner material, the ozone may be produced using an ozonator, which may be fluidly coupled with an inlet of the processing chamber.

Given the ample supply of the oxygen-containing precursor and proper operating conditions, in some embodiments, substantially all the molybdenum-containing first liner formed on the sidewalls of the trench 505 may be oxidized, and portions of the molybdenum regions 525 inside the lateral recesses 527 of the trench 505 may also be oxidized, as illustrated in FIG. 5C. Slightly etching molybdenum inside the lateral recesses 527 may ensure separation of the molybdenum regions 525 when the oxidized molybdenum may be removed in subsequent operations of method 400. As is also shown in FIG. 5C, during the oxidation operation 420, when the oxide or nitride barriers 545 include nitride, portions of the oxide or nitride barriers 545 contacting the molybdenum oxide 555 may also be oxidized to form oxidized portions of nitride barriers 560.

Once the molybdenum-containing first liner formed on at least a portion of the sidewalls 540 of the trench 505 is oxidized, along with portions of the molybdenum regions 525 in some embodiments, the oxidization operation 420 may be paused by halting the flow of the oxygen-containing precursor. In embodiments, residual plasma effluents may be purge prior to operation 425. At operation 425, a halide precursor may be provided to the processing region. The halide precursor may include a metal halide or other halogen-containing precursors that may interact with molybdenum oxide and/or liner material. In embodiments, the halide precursor may be or include a chlorine-containing precursor or a fluorine-containing precursor. The halide precursor may include tungsten chloride, such as tungsten pentachloride, and/or tungsten fluoride, such as tungsten hexafluoride. At operation 430, the halide precursor may modify and interact with the molybdenum oxide 555 to form volatile substances, which may then be removed from the chamber. The volatile substances formed from the halide precursor and the molybdenum oxide 555 may include molybdenum oxychloride and/or molybdenum oxyfluoride. Once the molybdenum oxide 555 is removed by the halide precursor, the underlying oxide or nitride barriers 545, which may also be oxidized as discussed above, may be exposed. Although the exposed portions of the oxide or nitride barriers 545 may interact with the halide precursor without being first oxidized, oxidation of the oxide or nitride barriers 545 to form oxidized portions of nitride barriers 560 may improve the etch rate.

The etch rate of oxidized portions of the liner material by the halide precursor may be at least about 2 times, about 3 times, about 4 times, about 5 times, about 6 times, about 7 times, about 8 times, or more of the etch rate of non-oxidize portions of the liner material by the halide precursor. The volatile substances formed from the halide precursor and the oxidized portions of nitride barriers 560 may include a metal oxychloride, a metal oxyfluoride, a metal chloride, such as a metal tetrachloride, and/or a metal fluoride, such as a metal tetrafluoride. The halide precursor may be delivered during operation 425 for a time period between about 15 seconds and about 5 minutes. The halide precursor delivery may last at least about 30 seconds, 1 minute, 1.5 minutes, 2 minutes, 2.5 minutes, 3 minutes, 3.5 minutes, 4 minutes, 4.5 minutes, 5 minutes, or longer in embodiments to ensure complete removal of the molybdenum oxide 555 and/or the oxidized portions of nitride barriers 560. As shown in FIG. 5D, the molybdenum oxide 555 and/or the oxidized portions of nitride barriers 560 may be removed upon completion of etching operation 430, and the molybdenum regions 525 may be separated from one another.

At the etching operation 430, the molybdenum oxide 555 and the oxidized portions of nitride barriers 560 may be selectively removed relative to the other materials and structures on the substrate, including the molybdenum regions 525, the oxide or nitride barriers 545 interposed between the molybdenum regions 525 and the gate dielectric 550, and the gate dielectric 550. Without intending to be bound to any particular theory, the gate dielectric 550 may not be etched by the halide precursor partly because the bonding between oxygen and metal in the gate dielectric may be stronger than the bonding between oxygen and molybdenum and/or the bonding between oxygen and metal in the gate dielectric, and partly because the reactive products, if any, may include metal fluorides and/or metal oxyfluorides, which may be substantially non-volatile under the operating conditions for the etch operation 430. Although not explicitly illustrated in FIG. 5D, method 400 may also selectively remove the molybdenum oxide 555 and the oxidized portions of nitride barriers 560 relative to silicon oxide, such as the silicon oxide layers 520, and relative to silicon nitride, which may form the charge trap layers for the memory cells.

Because the halide precursor may selectively etch only the molybdenum oxide 555 and/or the oxidized portions of nitride barriers 560, and because the oxidation operation 420 may yield substantially uniform top to bottom loading as discussed above, the etching operation 430 may also yield substantially uniform top to bottom loading. The etched thickness of the molybdenum layer proximate an upper region of the trenches may differ from the etched thickness of the molybdenum layer proximate a lower region of the trenches etched by method by less than or about 30%, less than or about 25%, less than or about 20%, less than or about 15%, less than or about 10%, less than or about 5%, less than or about 3%, less than or about 1%, or less in embodiments. Accordingly, a ratio of less than or about 1.3:1, less than or about 1.25:1, less than or about 1.2:1, less than or about 1.15:1, less than or about 1.1:1, less than or about 1.05:1, or a ratio of substantially or essentially 1:1 top to bottom loading of molybdenum etching may be achieved utilizing method 400. Such uniform top to bottom loading may prevent or limit over-etching of the molybdenum regions 525 inside the lateral recesses 527 of the trench while facilitating complete removal of the molybdenum that may be deposited on the sidewalls 540 and/or the bottom 535 of the trench 505 to ensure separation of the molybdenum regions 525 from each other.

Additionally, using the halide precursor as the etchant may further improve the top to bottom loading due to the isotropic etching it may offer. As compared to conventional reactive ion etching methods, which may impart directionality and make it difficult to laterally etch the molybdenum oxide 555 and/or the oxidized portions of nitride barriers 560 lining the sidewalls of the trench 505, the halide precursor may react with the molybdenum oxide 555 and/or the oxidized portions of nitride barriers 560 substantially uniformly inside the trench 505, resulting in a virtually isotropic etching of the molybdenum oxide 555 and/or the oxidized portions of nitride barriers 560 inside the trench 505. Such uniformity may be facilitated by maintaining a pressure within the processing chamber above or about 10 Torr, above or about 15 Torr, above or about 20 Torr, above or about 25 Torr, above or about 30 Torr, above or about 35 Torr, above or about 40 Torr, above or about 45 Torr, above or about 50 Torr, above or about 55 Torr, above or about 60 Torr, above or about 70 Torr, above or about 80 Torr, above or about 90 Torr, above or about 100 Torr, or higher. Higher pressure inside the processing chamber may reduce the mean free path of the halide precursor and may achieve a non-directional flow of the halide precursor, thereby achieving the isotropic etching inside the trenches. Alternatively, in some embodiments, during the etching operation 430, the pressure within the processing chamber may be maintained below or about 100 Torr, below or about 90 Torr, below or about 80 Torr, below or about 70 Torr, below or about 60 Torr, below or about 55 Torr, below or about 50 Torr, below or about 45 Torr, below or about 40 Torr, below or about 35 Torr, below or about 30 Torr, below or about 25 Torr, below or about 20 Torr, below or about 15 Torr, below or about 10 Torr, below or about 5 Torr, below or about 1 Torr, or lower. Accordingly, in some embodiments, method 400 may further include adjusting the operating conditions (e.g., temperature, pressure, both, etc.) within the processing chamber between the oxidation operation and the etching operation. For example, in some embodiments, the pressure may be adjusted from below or about 5 Torr during the oxidation, to a pressure above or about 10 Torr. Any of the previously discussed pressures or ranges may similarly be used during the two operations.

As discussed above, a relatively higher temperature may be maintained within the processing chamber or at the substrate level during the oxidation operation 420 of method 400 to facilitate uniform oxidation. In some embodiments, during the etching operation 430, a relatively lower temperature may be maintained within the processing chamber or at the substrate level. Due to the high volatility of the byproducts formed using the halide precursor, a higher temperature may not be required for effective etching to be achieved. Additionally, a relatively lower temperature may also limit or prevent surface migration of any non-volatile or less volatile byproducts that may be formed, such as aluminum fluoride as discussed above. During the etching operation 430, the temperature within the processing chamber or at the substrate level may be maintained between about 250° C. and about 400° C. during the etching operation 430. In some embodiments, the temperature may be maintained below or about 400° C., and may be maintained below or about 350° C., below or about 300° C., below or about 250° C., or lower in embodiments. In some embodiments, to increase reaction rates, a relatively higher temperature may be maintained within the processing chamber or at the substrate level during the etching operation 430. In some embodiments, the temperature maintained within the processing chamber or at the substrate level during the etching operation 430 may be similar to or even greater than the temperature maintained within the processing chamber or at the substrate level during the oxidation operation 420. Accordingly, during the etching operation 430, the temperature within the processing chamber or at the substrate level may be maintained greater than or about 400° C., greater than or about 450° C., greater than or about 500° C., greater than or about 550° C., greater than or about 600° C., or even higher.

There may be several ways to maintain different temperatures in the processing chamber or at the substrate level during the oxidation operation 420 and the etching operation 430. When the oxidation operation 420 may be paused, the temperature in the processing chamber or at the substrate level may be lowered or increased to a desired level before initiating the flow of the halide precursor at operation 425. Alternatively or additionally, in some embodiments, during the oxidation operation 420, the substrate may be positioned close to a heating source inside the processing chamber so as to achieve a relatively high temperature at the substrate level, and subsequent to the oxidation operation 420, the substrate may be moved away from the heating source so as to lower the temperature at the substrate level for the etching operation 430. For example, showerhead 225 may include a heater or may be configured to be heated in some embodiments. During the oxidation operation, the substrate may be positioned proximate the showerhead to increase the substrate and operating temperature, and the substrate may be positioned at a first distance from the heating source. Subsequent to the oxidation operations, the substrate may be translated away from the showerhead to a second distance from the heating source, such as by lowering a pedestal height, to reduce the heating effect. The etching operation may then be performed at a second temperature lower than the first temperature when the substrate is moved. In some embodiments where the etching operation may be performed at a higher temperature than the oxidation operation 420, the substrate may be positioned further away from the heating source inside the processing chamber so as to achieve a relatively lower temperature at the substrate level during the oxidation operation 420, and subsequent to the oxidation operation 420, the substrate may be moved closer to the heating source so as to increase the temperature at the substrate level for the etching operation 430.

In still other embodiments, the oxidation operation 420, as well as the operation 405 and optionally, operations 410, 415 for producing the oxygen-containing plasma effluents, may be performed in a chamber separate from the chamber to which the halide precursor may be providing at operation 425 to start the etching operation 430. Utilizing two chambers maintained at different temperatures for the oxidation operation 420 and the etching operation 430, respectively, may involve extra time for transporting the substrate from one chamber to the other. However, processing time may be saved due to the fact that no temperature adjustment may be required inside each chamber and sufficient oxidation may be ensured in one cycle, thereby reducing overall processing time.

In some embodiments, depending on the thickness of the molybdenum-containing first liner formed on at least a portion of the sidewalls of the trench, method 400 may be performed in cycles to facilitate complete oxidation and removal of the molybdenum outside the lateral recesses to ensure separation of the molybdenum regions from one another. As shown in FIG. 4, the method 400 may include repeating the oxidation operations 405-420 and etch operations 425-430. As discussed above, depending on the processing conditions, the initial rapid oxidization of neat or clean molybdenum may produce a molybdenum oxide layer having a thickness between about 10 Å and about 400 Å or more before the oxidization process slows down. To improve processing efficiency, oxidation of the molybdenum may be paused after the initial rapid oxidization, and removal of the oxidized molybdenum may be initiated. After removal of the molybdenum, the flow of the oxygen-containing precursor may be resumed to initiate another cycle of method 400. In some embodiments, two or more cycles, such as three cycles, four cycles, five cycles, or more, of oxidation and removal operations may be performed to achieve complete removal of the molybdenum-containing first liner formed on at least a portion of the sidewalls of the trenches.

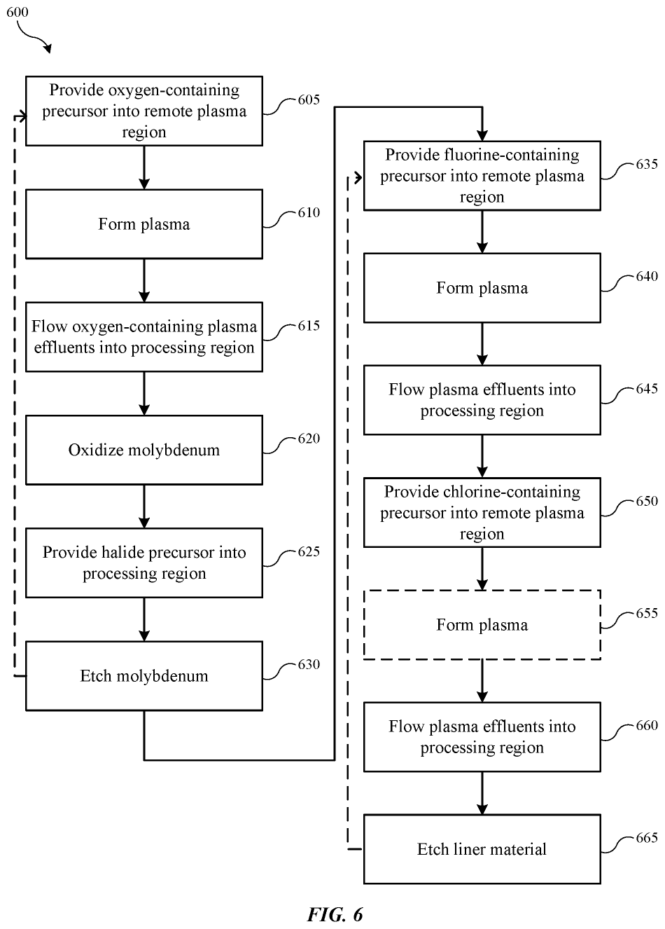

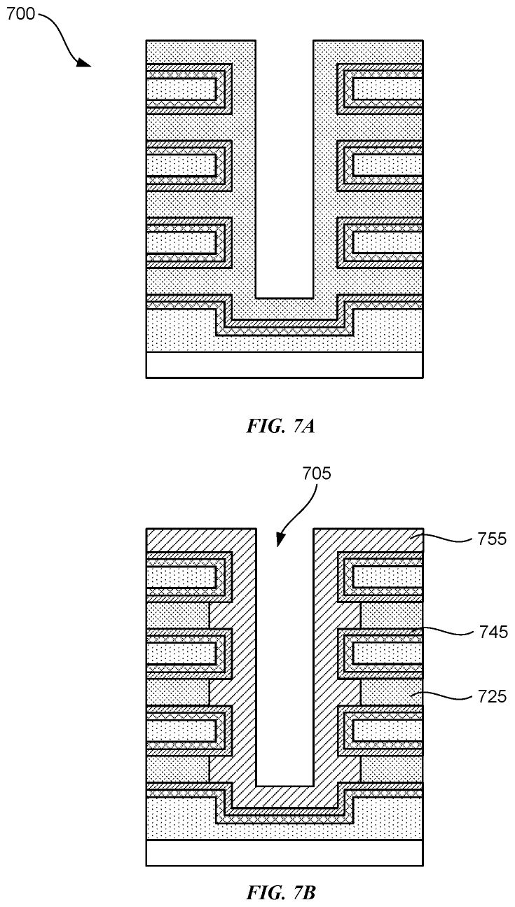

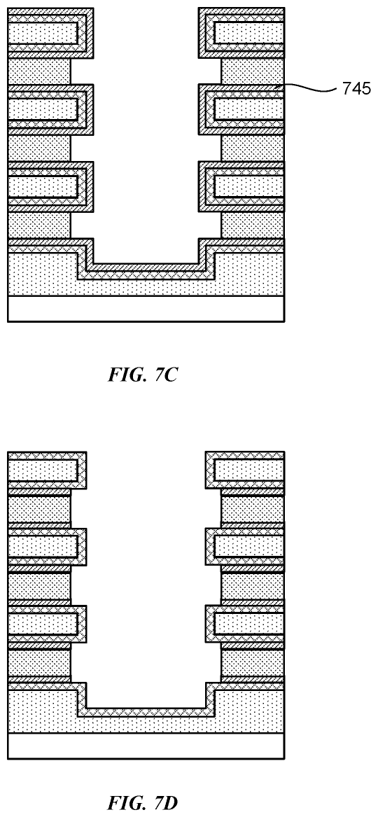

Turning to FIG. 6, exemplary operations of another method 600 are shown according to embodiments of the present technology. The operations of method 600 are also schematically illustrated in FIGS. 7A-7D, which illustrate a processed structure 700 similar to the processed structure 500 in FIGS. 5A-5D. Method 600 may include operations 605-630 similar to operations 405-430 of method 400. In some embodiments, method 600 may include providing an oxygen-containing precursor to a remote plasma region of the semiconductor processing chamber at operation 605. The remote plasma region may be a remote plasma system (RPS) fluidly coupled with the processing region, or may include a capacitively-coupled plasma (CCP) region, as discussed above with reference to method 400. Method 600 may further include forming a plasma of the oxygen-containing precursor at operation 610 to produce oxygen-containing plasma effluents, and providing the oxygen-containing plasma effluents to the processing region at operation 615. At operation 620, the oxygen-containing plasma effluents may contact and oxidize the molybdenum connecting the molybdenum regions 725 to form a molybdenum oxide 755 inside and on top of the trench 705 as shown in FIG. 7B. The oxygen-containing precursor may include a variety of fluids, and may include one or more of atomic oxygen, molecular oxygen (O₂), N₂O, NO, NO₂, CO₂, ozone (O₃), or any other oxygen-containing precursor that may similarly perform the oxidation operation.

Although FIG. 6 illustrates oxidizing molybdenum using oxygen-containing plasma, method 600 may include providing molecular oxygen (O₂), ozone (O₃), or other oxygen-containing precursors, instead of providing plasma effluents, to the processing region to oxidize molybdenum. In the embodiments where molecular oxygen may be utilized for oxidizing molybdenum, the temperature within the processing chamber or at the substrate level may be maintained between about 250° C. and about 600° C. In the embodiment where ozone may be utilized for oxidizing molybdenum, the ozone may be produced using an ozonator, which may be fluidly coupled with an inlet of the processing chamber.

Residual plasma effluents may be purge prior to operation 625. At operation 625, a halide precursor may be provided to the processing region. The halide precursor may include a metal halide or other halogen-containing precursors that may interact with molybdenum oxide. The metal halide may include tungsten chloride, such as tungsten pentachloride, and/or tungsten fluoride, such as tungsten hexafluoride. At operation 630, the halide precursor may modify and interact with the molybdenum oxide 755 to form volatile substances, which may then be removed from the chamber. The volatile substances formed from the halide precursor and the molybdenum oxide 755 may include molybdenum oxychloride and/or molybdenum oxyfluoride.

Method 600 may differ from method 400 in that the operating conditions may be adjusted in method 600 such that gate metal barriers, such as oxide or nitride barriers 745, may not be oxidized as shown in FIG. 7B, or at least may not be fully oxidized. Accordingly, upon completion of the etching operation 630 for etching the molybdenum oxide 755, the oxide or nitride barriers 745 may not be etched and portions thereof may be exposed as shown in FIG. 7C. Residual plasma effluents may be purge prior to operation 635. To remove the exposed portions of the oxide or nitride barriers 745, method 600 may include providing a fluorine-containing precursor and, optionally, a hydrogen-containing precursor to a remote plasma region of the processing chamber at operation 635. Again, the remote plasma region may be a remote plasma system (RPS) fluidly coupled with the processing region, or may include a capacitively-coupled plasma (CCP) region, as discussed above. Method 600 may further include forming a plasma of the fluorine-containing precursor and, optionally, the hydrogen-containing precursor at operation to produce fluorine-containing plasma effluents and, optionally, hydrogen-containing plasma effluents, which may be provided to the processing region at operation 645. The plasma effluents of the fluorine-containing precursor and, optionally, the plasma effluents of the hydrogen-containing precursor may form a fluorinated portion of the oxide or nitride barriers 745.

The fluorine-containing precursor may include at least one precursor selected from the group of atomic fluorine, diatomic fluorine, nitrogen trifluoride, carbon tetrafluoride, hydrogen fluoride, xenon difluoride, and various other fluorine-containing precursors used or useful in semiconductor processing. An exemplary fluorine-containing precursor used in method 600 may include nitrogen trifluoride. Other sources of fluorine may be used in conjunction with or as replacements for the nitrogen trifluoride. The hydrogen-containing precursor may include diatomic hydrogen, a hydrocarbon, water, hydrogen peroxide, or other materials that may include hydrogen. The precursors may also include any number of carrier gases, which may include nitrogen, helium, argon, or other noble, inert, or useful precursors.

Residual plasma effluents may be purge prior to operation 650. Subsequent to forming a fluorinated portion of the oxide or nitride barriers 745, the method 600 may include providing a chlorine-containing precursor to a remote plasma region of the processing chamber at operation Method 600 may further include forming a plasma of the chlorine-containing precursor at optional operation 655 to produce chlorine-containing plasma effluents, which may be provided to the processing region at operation 660. In embodiments, the method 600 may not include forming a plasma of the chlorine-containing precursor, as some chlorine-containing precursors may be used in a thermal etch. The chlorine-containing precursor may include at least one precursor selected from the group of atomic chlorine, diatomic chlorine, boron trichloride, and various other chlorine-containing precursors used or useful in semiconductor processing. An exemplary chlorine-containing precursor used in method 600 may include boron trichloride. Other sources of chlorine may be used in conjunction with or as replacements for the boron trichloride. The precursors may also include any number of carrier gases, which may include nitrogen, helium, argon, or other noble, inert, or useful precursors.

At operation 665, the plasma effluents of the chlorine-containing precursor may interact with the fluorinated portion of the oxide or nitride barriers 745 to form volatile byproducts thereby removing the fluorinated portion of the oxide or nitride barriers 745 as shown in FIG. 7D. Operation 665 may selectively etch the second liner over molybdenum and/or molybdenum oxide. The temperature and/or pressure of the processing chamber may be maintained similar to the temperature and/or pressure utilized in the oxidation operation of the molybdenum to facilitate removal of the exposed portions of the oxide or nitride barriers 745. In other embodiments, the operating temperature and/or pressure during the removal of the barrier materials may be similar to the operating temperature and/or pressure during removal of the molybdenum oxide.

In embodiments, any one of the fluorine-containing precursor, the hydrogen-containing precursor, or the chlorine-containing precursor may bypass the remote plasma region and be provided to additional regions of the processing chamber. For example, while the fluorine-containing precursor may be provided through the remote plasma region to produce fluorine-containing plasma effluents, the hydrogen-containing precursor may bypass the remote plasma region. The hydrogen-containing precursor may bypass the remote plasma region by a bypass at a top of the chamber, or may be provided into a separate region of the chamber, such as through a port providing access to the volume within the showerhead, such as showerhead 225 of FIG. 2A. The hydrogen-containing precursor may then be provided to the processing region, where it may then mix or interact with fluorine-containing plasma effluents.

In some embodiments, depending on the thickness of the molybdenum-containing first liner formed on at least a portion of the sidewalls of the trench and/or the thickness of the oxide or nitride barriers 745, method 600 may be performed in cycles to facilitate complete oxidation and removal of the molybdenum and/or oxide or nitride barriers 745 outside the lateral recesses to ensure separation of the molybdenum regions from one another. As shown in FIG. 6, the method 600 may include repeating the oxidation operations 605-620 and etch operations 625-630, as well as operations 665-635. Depending on the processing conditions, the initial rapid oxidization of neat or clean molybdenum may produce a molybdenum oxide layer having a thickness between about 10 Å and about 400 Å or more before the oxidization process slows down. To improve processing efficiency, oxidation of the molybdenum may be paused after the initial rapid oxidization, and removal of the oxidized molybdenum may be initiated. After removal of the molybdenum, the flow of the oxygen-containing precursor may be resumed to initiate another cycle of method 600. In some embodiments, two or more cycles, such as three cycles, four cycles, five cycles, or more, of oxidation and removal operations may be performed to achieve complete removal of the molybdenum-containing first liner formed on at least a portion of the sidewalls of the trenches. The same may be true for the removal of the liner material.

Subsequent to operation 665, the molybdenum-containing metal regions may be partially surrounded by the liner material, such surrounded on three sides by the liner material. Furthermore, molybdenum-containing material in each recess may be isolated from molybdenum-containing material in the remaining plurality of recesses.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing an oxygen-containing precursor to a semiconductor processing chamber, wherein a substrate is positioned within the semiconductor processing chamber, wherein the substrate comprises:
a trench formed between columns; and
molybdenum-containing metal regions in a plurality of recesses formed in at least one of the columns, wherein at least two of the molybdenum-containing metal regions are connected by a molybdenum-containing first liner formed on at least a portion of a sidewall of the trench;
forming a plasma of the oxygen-containing precursor in the semiconductor processing chamber;
contacting the molybdenum-containing first liner with plasma effluents of the oxygen-containing precursor, wherein the contacting forms an oxidized portion of molybdenum on the molybdenum-containing first liner;
providing a halide precursor to the semiconductor processing chamber; and
contacting the oxidized portion of molybdenum with plasma effluents of the halide precursor, wherein the contacting removes the oxidized portion of molybdenum from the sidewall of the trench.

2. The semiconductor processing method of claim 1, wherein the oxygen-containing precursor comprises ozone.

3. The semiconductor processing method of claim 1, wherein the plasma of the oxygen-containing precursor is formed at a plasma power less than or about 2,000 W.

4. The semiconductor processing method of claim 1, wherein the oxidized portion of molybdenum is characterized by a thickness of less than or about 100 Å.

5. The semiconductor processing method of claim 1, wherein the halide precursor comprises a fluorine-containing precursor.

6. The semiconductor processing method of claim 5, wherein the fluorine-containing precursor comprises tungsten hexafluoride.

7. The semiconductor processing method of claim 1, wherein forming the oxidized portion of molybdenum produces a layer of molybdenum oxide formed along a sidewall of the trench, and wherein a thickness of the layer of molybdenum oxide proximate an upper region of the trench differs in thickness from the layer of molybdenum oxide proximate a lower region of the trench by less than or about 30%.

8. The semiconductor processing method of claim 1, wherein the substrate further comprises a second liner disposed adjacent to the molybdenum-containing metal regions and the molybdenum-containing first liner, the method further comprising:
providing a fluorine-containing precursor to the semiconductor processing chamber;
forming a plasma of the fluorine-containing precursor to produce fluorine-containing plasma effluents;
contacting the second liner with the fluorine-containing plasma effluents to form a fluorinated portion of the second liner;
providing a chlorine-containing precursor to the semiconductor processing chamber;
forming a plasma of the chlorine-containing precursor to produce chlorine-containing plasma effluents; and
contacting the fluorinated portion of the second liner with the chlorine-containing plasma effluents, wherein the contacting removes the fluorinated portion of the second liner.

9. The semiconductor processing method of claim 1, wherein the contacting of the molybdenum-containing first liner with plasma effluents of the oxygen-containing precursor and the contacting the oxidized portion of molybdenum with plasma effluents of the halide precursor is repeated at least two times.

10. A semiconductor processing method comprising:
i) forming plasma effluents of an oxygen-containing precursor;
ii) contacting a molybdenum-containing first liner connecting at least two molybdenum-containing metal regions arranged within a plurality of recesses defined by at least one column of a trench with plasma effluents of the oxygen-containing precursor, wherein the contacting forms an oxidized portion of molybdenum on the molybdenum-containing first liner;
iii) forming plasma effluents of a fluorine-containing precursor; and
iv) contacting the oxidized portion of molybdenum with plasma effluents of the fluorine-containing precursor, wherein the contacting removes the oxidized portion of molybdenum.

11. The semiconductor processing method of claim 10, wherein operations i) through iv) are repeated at least two times.

12. The semiconductor processing method of claim 10, wherein:
the oxygen-containing precursor comprises ozone; and
the fluorine-containing precursor comprises tungsten hexafluoride.

13. The semiconductor processing method of claim 10, wherein a temperature is maintained at between about 200° C. and about 600° C. during operations i) and ii).

14. The semiconductor processing method of claim 10, wherein a pressure is maintained at less than or about 20 Torr during operations i) and ii).

15. The semiconductor processing method of claim 10, further comprising:
adjusting a temperature, a pressure, or both prior to contacting the oxidized portion of molybdenum with plasma effluents of the fluorine-containing precursor.

16. The semiconductor processing method of claim 10, further comprising:
a second liner disposed adjacent to the molybdenum-containing metal regions and the molybdenum-containing first liner, the method further comprising:
forming a plasma of a fluorine-containing precursor to produce fluorine-containing plasma effluents, wherein the fluorine-containing precursor comprises nitrogen trifluoride;
contacting the second liner with the fluorine-containing plasma effluents to form a fluorinated portion of the second liner;
forming a plasma of a chlorine-containing precursor to produce chlorine-containing plasma effluents, wherein the chlorine-containing precursor comprises boron trichloride; and
contacting the fluorinated portion of the second liner with the chlorine-containing plasma effluents, wherein the contacting removes the fluorinated portion of the second liner.

17. The semiconductor processing method of claim 16, wherein the second liner comprises an oxygen-containing material, a nitrogen-containing material, or an oxygen-and-nitrogen-containing material.

18. A semiconductor structure comprising:
a substrate;
a silicon-containing material overlying the substrate, wherein the substrate comprises a trench formed between columns, and wherein at least one column defines a plurality of recesses;
a liner extending along the at least one column and into the plurality of recesses; and
molybdenum-containing metal regions formed in the plurality of recesses, wherein the molybdenum-containing metal regions are partially surrounded by the liner, and wherein a thickness of the molybdenum-containing metal regions in a recess proximate an upper region of the trench differs in thickness from the molybdenum-containing metal regions in a recess proximate a lower region of the trench by less than or about 30%.

19. The semiconductor structure of claim 18, wherein the trench is characterized by a depth of greater than or about 5 μm.

20. The semiconductor structure of claim 18, wherein:
the molybdenum-containing metal regions is surrounded by the liner on three sides; and
the molybdenum-containing metal regions in one recess is isolated from molybdenum material in a remaining plurality of recesses.
